(19) United States
(12) Patent Application Publication
(10) Pub. No.: US 2023/0168408 A1
(43) Pub. Date: Jun. 1, 2023

(54) SYSTEM TO DETECT THE PASSAGE OF SMALL ANIMALS THROUGH AN OPENING

(71) Applicant: POLITECNICO DI MILANO, Milano (IT)

(72) Inventors: Dario Andrea Nicola NATALI, Bergamo (IT); Luis Francisco Mollá MUNILLA, El Masnou (ES)

(73) Assignee: POLITECNICO DI MILANO, Milano (IT)

(21) Appl. No.: 17/921,187

(22) PCT Filed: Apr. 15, 2021
(86) PCT No.: PCT/IB2021/053100

§ 371 Date: Oct. 25, 2022

(30) Foreign Application Priority Data
May 20, 2020 (IT) 102020000011791

(51) Int. Cl. G01V 3/08; A01K 29/00; A01K 47/06

(52) U.S. Cl. CPC G01V 3/088; A01K 29/005; A01K 47/06

(57) ABSTRACT

A system to detect the passage of a small animal through an opening. The system includes a first capacitor and a second capacitor arranged sequentially along a direction substantially perpendicular to the plane of the opening. Each of the capacitors includes two electrodes arranged on the outside of the opening and having substantially a U shape. An evaluation unit is electrically connected to the two capacitors to evaluate the change in capacitance of at least one of the two capacitors produced by the passage of an animal through the opening.

### TECHNICAL FIELD

The present invention relates to the field of systems to detect the passage of small animals, such as bees, insects, and mice, through an opening. The invention finds preferred and advantageous application in monitoring the state of health of a hive.

### BACKGROUND

At the state of the art, several systems are known to monitor the passage of small animals, such as insects or small rodents.

The monitoring of insects and small animals has many reasons and applications. In the case of bees, for example, monitoring the entry and exit of bees in the beehive is of fundamental importance to understand the state of health of the hive.

In particular, knowing whether the number of outgoing bees is about the same as the number of incoming bees is important in detecting the presence of hive depopulation syndrome. This syndrome is a still little known phenomenon, whose causes are not well known (some theories refer to stress due to environmental changes, loss of territory, malnutrition, various pathogens such as the Israeli Acute Paralysis Virus, the presence of pesticides) but it is known to be characterized by the failure of bees to return to the hive.

There is therefore a need for the beekeeper to monitor precisely how many bees are entering and leaving the beehive.

Some systems to monitor the passage of small animals, such as bees, through openings use optical sensors, while other systems use capacitive sensors.

From patent application BE1011050A6, a method for measuring and a device for recording insect activity, carried out by applying a counting system that records the number of passages to and from the insect colony, is known. In particular, a plurality of passage channels provided with a single LED activating a pair of photodiodes spaced 1 mm apart is used to enable motion detection.

Near of the passage channel, the walking surface shows a change of level. This prevents a continuous passage of insects through the channels. An asynchronous sequential algorithm is used for each channel to determine the entry and exit direction of the insects. The change of level introduced to prevent the continuous passage of insects may, however, annoy the bees, which, annoyed, may decide to move elsewhere.

US2004077290 describes an integrated system to monitor bee colonies in a hive. The system has a central microprocessor, at least two input transducers and at least two output signals. Input transducers comprise sensors that report the colony status, including the colony weight, temperature, and relative humidity. A bee counter may also be included in the system to indicate the colony activity. A bee counter using an amplifier, a circuit with hysteresis, and a debounce circuit is described to enable a fast and accurate polling of a single passage. The information collected can be retrieved by readout or liquid crystal display. Alternatively, information may be retrieved via telephone line or wireless communications. The system to monitor bees can also remotely control peripheral devices such as feeders or chemical samplers.

A system to monitor the passage of bees is also described in the article by Jennifer M Campbell et al, 2005 Meas. Sci. Technol. 16 2503, “Capacitance-based sensor for monitoring bees passing through a tunnel”. The system is used to monitor a colony of bumblebees and starts from the consideration that LED-based monitoring systems are inefficient in monitoring bees, which carry pollen that ends up dirtying the detectors. Thus, the solution proposed by Campbell et al. involves the use of a capacitive sensor to monitor bees and insects passing through a tunnel. The sensor includes a pair of capacitors placed externally to the tunnel and arranged in sequence along the direction of passage of the insects. The passage of the insects through the capacitors generates a change in capacitance that is read and interpreted by an evaluation unit that counts the passage of insects and their direction of movement: entry or exit.

The solution described in Campbell et al., although efficient, appears impractical to be applied to existing beehives. In the beehives, the bees pass through openings obtained in the box-shaped body of the beehive and it is difficult to apply, in an easy way, the parallel plate or ring electrodes provided by Campbell et al. In addition, bees are habitual and providing, at the entrance to the beehive, a conduit to which to apply the electrode configurations described by Campbell could annoy them and alter their normal behaviour.

A bee counter is also sold by Melixa S.r.l., which has also described it in the patent application US2017071169A1. The counter is placed in front of the opening of the beehive and has a plurality of conduits through which the bees must pass. Also in this case, the counter is cumbersome and, by considerably modifying the entry of the beehive, forces the bees to change habits and could create the conditions to cause a migration from the hive making the measurement unreliable.

### OBJECTS AND SUMMARY OF THE INVENTION

It is an object of this invention is to overcome the drawbacks of the prior art.

In particular, it is an object of the present invention to present a system to monitor the passage of small animals through an opening that interferes as little as possible with the habits of the monitored animals.

A further object of the present invention is to present a system to monitor the passage of small animals through an opening that is easy to install.

These and other objects of the present invention are achieved by a system incorporating the features of the annexed claims, which form an integral part of the present description.

According to a first aspect, the present invention is directed to a system to detect the passage of an animal—in particular, a small animal—through an opening. The system comprises a first capacitor and a second capacitor arranged sequentially along a direction substantially perpendicular to the plane of the opening. Each of the capacitors comprises two electrodes—possibly one in common—intended to be placed in front of the opening and being substantially U-shaped. An evaluation unit is electrically connected to the two capacitors to evaluate the change in capacitance of the two capacitors produced by the passage of an animal through the opening.

This solution is very effective to monitor the passage of animals without disturbing their habits, as the particular U-shaped electrodes lend themselves to a simple and quick installation that does not alter the walking surface on which the animals move.

Preferably, the evaluation unit is configured to evaluate the difference in the capacitances of the two capacitors such that a direction of movement of the animal through the opening is discriminated.

In an embodiment, the first and second capacitors are placed inside a crossing module comprising a box body in turn comprising a front wall, a rear wall, side walls connecting the front wall to the rear wall, and a lower surface closing the box body at the bottom. The rear wall and the front wall comprise a respective passage opening, while the lower surface of the crossing module comprises support areas from which channel walls rise up, which define a passage channel between the passage opening provided in the front wall and the passage opening provided in the rear wall. The electrodes are placed inside the crossing module and embrace the channel walls.

Thanks to this shape of the crossing module, a system is realized which can be easily placed on a plane in front of an opening to be monitored, for example the entrance of a beehive or a hole in a net.

Preferably, then, at least the front wall and/or the rear wall of the crossing module is made of metallic material to shield the electrodes of the capacitors and reduce noise. Advantageously, then, the metallic parts are coated with an insulating material, e.g., they are painted with insulating paint, so that the possible contact of the animal with such walls does not produce disturbances on the capacitance measurement of the two capacitors.

In a further embodiment, the front wall and the rear wall of the crossing module each comprise at least a second passage opening, and the lower surface comprises second channel walls that define at least a second channel between the second passage opening of the rear wall and the second passage opening of the front wall. The crossing module comprises a third and a fourth capacitor each including U-shaped electrodes embracing said second channel walls.

With this embodiment, it is therefore possible to monitor the simultaneous passage of animals through the different channels of the crossing module.

Advantageously, then the box body of the crossing module further comprises a separating wall that connects the front wall to the rear wall and is arranged between two adjacent passage openings.

The separating wall allows reducing possible interference between groups of capacitors monitoring adjacent channels. For this purpose, the separating wall is preferably made of metallic material.

In an embodiment, then, the evaluation unit comprises a neural network of the supervised learning type. This allows making an accurate count of the number of animals actually passing through the channels of the monitoring device, net of disturbances and errors that may arise due to the behaviour of the animals near or inside the channels.

According to a further aspect, the invention is also directed to a beehive comprising an opening for the entry and exit of bees and a system to monitor the passage of animals as set forth above and as further set forth in the following description. The system is positioned such that the first and second capacitor are placed in front of said opening for the entry and exit of bees.

Further features and advantages of the present invention will be more apparent from the description of the accompanying drawings.

### BRIEF DESCRIPTION OF THE DRAWINGS

The invention will be described below with reference to some examples, provided for explanatory and non-limiting purposes, and illustrated in the accompanying drawings. These drawings illustrate different aspects and embodiments of the present invention and, where appropriate, reference numbers illustrating similar structures, components, materials and/or elements in different figures are indicated by similar reference numbers.

FIG. 1 schematically illustrates a beehive according to the prior art;

FIG. 2 illustrates a device to monitor small animals according to an embodiment of the present invention;

FIG. 3 illustrates a top view of the device of FIG. 2;

FIG. 4 illustrates a side view of the device of FIG. 2;

FIG. 5 illustrates the device of FIG. 2 mounted in front of a beehive;

FIG. 6 illustrates a detail of the device of FIG. 2;

FIG. 7 illustrates a detail of the device of FIG. 2;

FIG. 8 illustrates a section of FIG. 7;

FIG. 9 schematically illustrates an electronic circuit of the device of FIG. 2;

FIG. 10 illustrates the signal measured during the entry of a bee into a beehive at whose entrance the device of FIG. 2 is placed;

FIG. 11 illustrates the signal measured during the exit of a bee in a beehive at the entrance of which the device of FIG. 2 is placed;

FIG. 12 illustrates a detail of a crossing module used in a variant of the device of FIG. 2.

### DETAILED DESCRIPTION OF THE INVENTION

While the invention is susceptible to various modifications and alternative constructions, certain preferred embodiments are shown in the drawings and are described hereinbelow in detail. It is in any case to be noted that there is no intention to limit the invention to the specific embodiment illustrated, rather on the contrary, the invention intends covering all the modifications, alternative and equivalent constructions that fall within the scope of the invention as defined in the claims.

The use of “for example”, “etc.”, “or” indicates non-exclusive alternatives without limitation, unless otherwise indicated. The use of “includes” means “includes, but not limited to” unless otherwise stated.

By the expression “small animal” it is intended to refer to an animal that has a size lower than 10 CM.

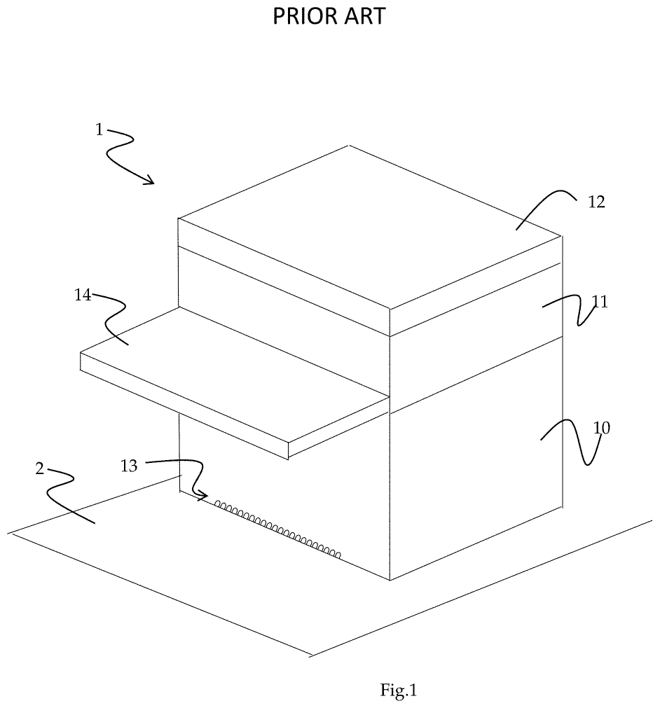

With reference to FIG. 1, a beehive 1 according to the prior art is shown. The beehive 1 comprises a box-shaped body which, in the example shown here, comprises two overlapping elements (a brood chamber 10 and a honey super 11) closed at the top by a roof 12. The lower element (the brood chamber 10) of the box-shaped body has, near the base, a plurality of openings 13 through which the bees enter and exit the beehive. A canopy 14 is placed above the openings 13 to shelter them from rain and foliage.

The beehive 1 is placed on a support surface 2 which also serves as a walking surface for bees entering the beehive.

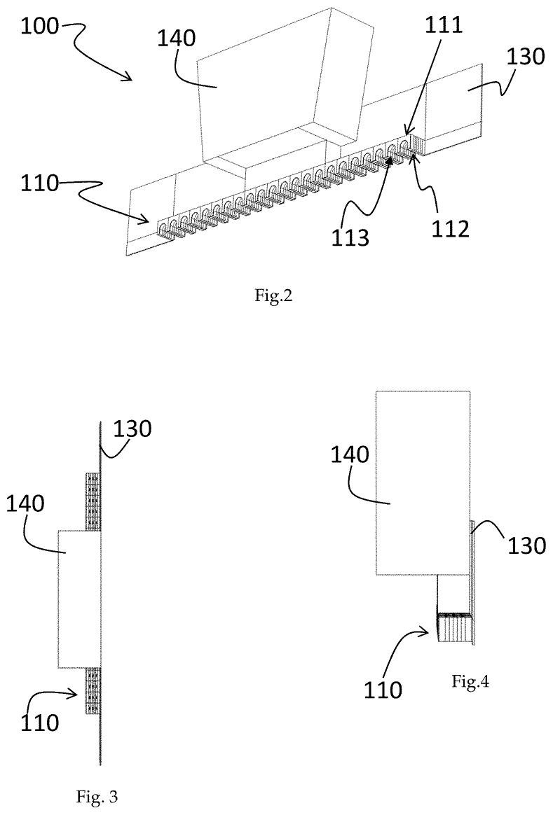

With reference to FIGS. 2 to 4, there is shown a device 100 to monitor small animals, in particular bees, according to an embodiment of the present invention.

A crossing module 110 comprising a plurality of arc elements 111 defining channels 112 crossing the monitoring device 100 is placed at the base of the monitoring device 100. Each channel has at its ends passage openings 113 lying in a plane orthogonal to the direction of development of the channel

The monitoring device 100 is also provided with a housing 140 for housing electronic components such as a PCB (Printed Circuit Board) board, transmitters etc... and power supply devices, such as a battery.

The housing 140 is in mechanical connection with the monitoring module, so as to protect the electrical connections between the components in the box-shaped body and the electrodes placed inside the crossing module 110.

In the example of FIGS. 2-4, the monitoring device 100 further comprises a panel 130 that structurally serves to hold the box-shaped body 140 and the crossing module 110 together. Such a panel 130 also provides a surface for fixing the device 100 to a wall. Obviously, the panel 130 is not indispensable and the device 100 can be realised with a crossing module 110 and a housing 140 having different shapes that do not need the structural function of the panel 130. Preferably, however, the housing 140 is arranged above the crossing module and has a rear wall aligned with the rear wall 115 of the crossing module.

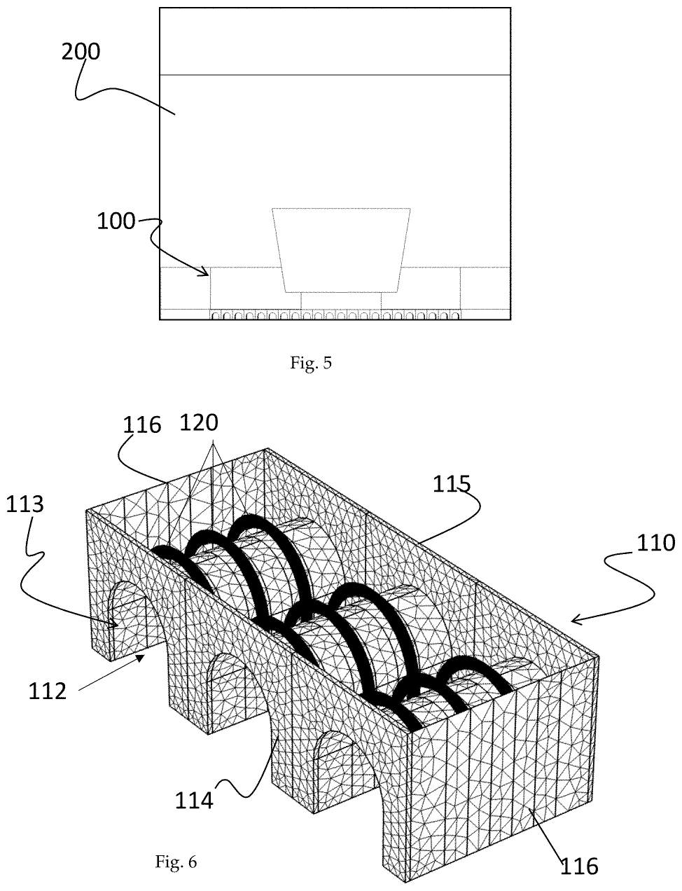

In the example of FIG. 5, the device 100 is mounted on the front side of a beehive 200 placing the channels 112 of the crossing module 110 in correspondence with the opening(s) placed at the base of the beehive 200 and resting the panel 130 against the outer wall of the beehive. In this way, the bees enter the beehive substantially without changing their habits, as they find the usual beehive opening extended by a few millimetres (the length of the channel 112), but no obstacle on the walking surface or change in path to enter the beehive.

FIG. 6 allows appreciating some details of the crossing module 110. The module 110 comprises a front wall 114 and a rear wall 115 in which passage openings 113 are formed. Front wall 114 and rear wall 115 are connected to each other by side walls 116. Preferably at least the front wall and/or the rear wall are made of metallic material to shield the electrodes, more preferably all the perimeter walls (114, 115 and 116) of the crossing module 110 are made of metallic material.

Advantageously, the metallic perimeter walls are coated on the outside with insulating material, for example they are painted with an insulating paint, so that possible disturbances in measurement due to contact of bees with such walls are avoided. Such a coating may then include the use of a thermal insulating material, so that sunny walls does not become excessively hot and may bother the bees.

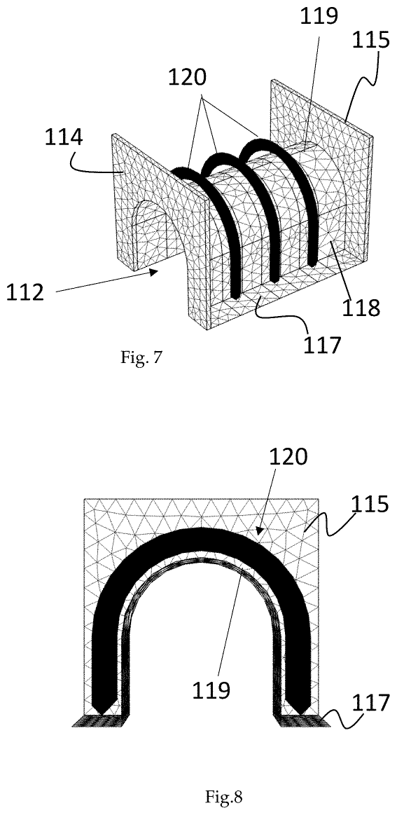

As can be seen in the detail of FIG. 7, the lower surface of the crossing module 110 comprises support areas 117 from which channel walls rise up, which define the channel 112. In the example described herein, the channel walls comprise vertical walls 118 closed at the top by a vault 119, however, channel walls of different shapes may be provided. Superiorly, the crossing module 110 is closed by a cover which, in FIG. 6, has been removed to allow the inside of the crossing module 110 to be shown.

At the vault of each channel 112, there are three U-shaped electrodes 120 arranged to embrace the vault of the channel 112. As is best visible in FIG. 8, in the preferred embodiment the electrodes 120 terminate in a pointed profile turned towards the support areas 117.

The electrodes 120 may be filiform or plate-like and are immersed inside an insulator, which is contained inside the crossing module 110 and not shown in the figures for reasons of clarity thereof. In a preferred embodiment the insulator is PMMA, however according to other embodiments the insulator may be selected from the group of materials consisting of HDPE, LLDPE, ABS.

The device 100 thus comprises two capacitors each consisting of a pair of electrodes 120 between which a dielectric (the insulator shown above) is interposed. In the example described herein, the two capacitors have a common electrode, so that in total only three electrodes are used for the two capacitors. The two capacitors are arranged sequentially along the channel, i.e., along a direction substantially perpendicular to the plane of the openings to be monitored.

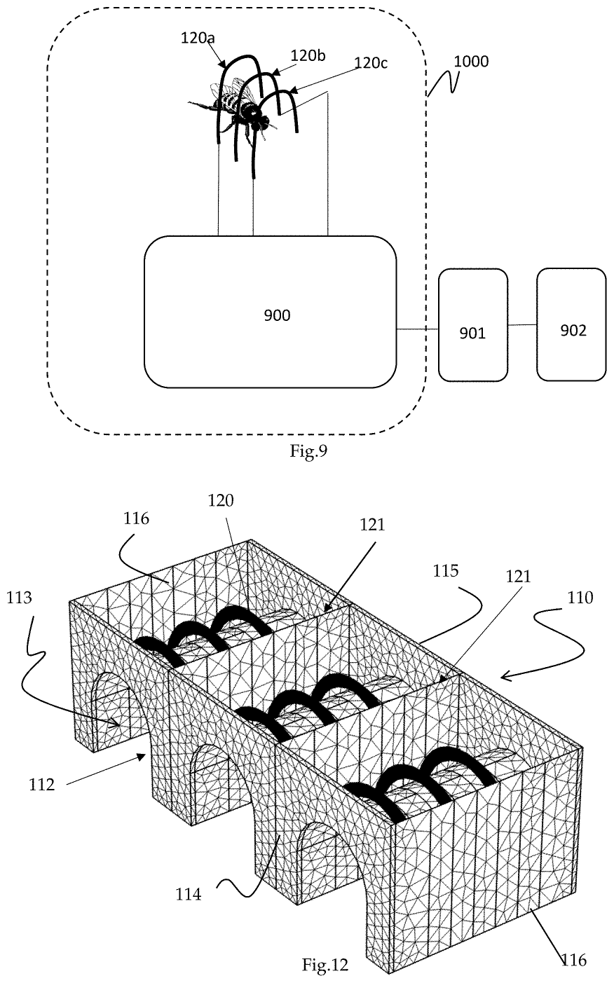

As schematically illustrated in FIG. 9, the three electrodes 120 (indicated 120a, 120b and 120c) divided by the insulating material are suitably connected to a measuring circuit 900 adapted to measure a change in capacitance of the two capacitors and in particular adapted to measure a change in the difference between the two capacitances. The circuit 900 is preferably a suitably programmed CDC (Capacitance to Digital Converter), e.g., the measuring circuit 900 can be made with the AD7746 chip by Analog Devices®. Alternatively, the circuit 900 can be realised by other circuitry, for example by using for each capacitor an impedance to digital converter (like AD5933 by Analog Devices®), or an AC bridge (whose branches are each the series of a suitable resistor and of one of the two capacitors to be measured) driven by a sinusoidal generator and an instrumentation amplifier to read the unbalance of the two branches induced by the passage of a bee.

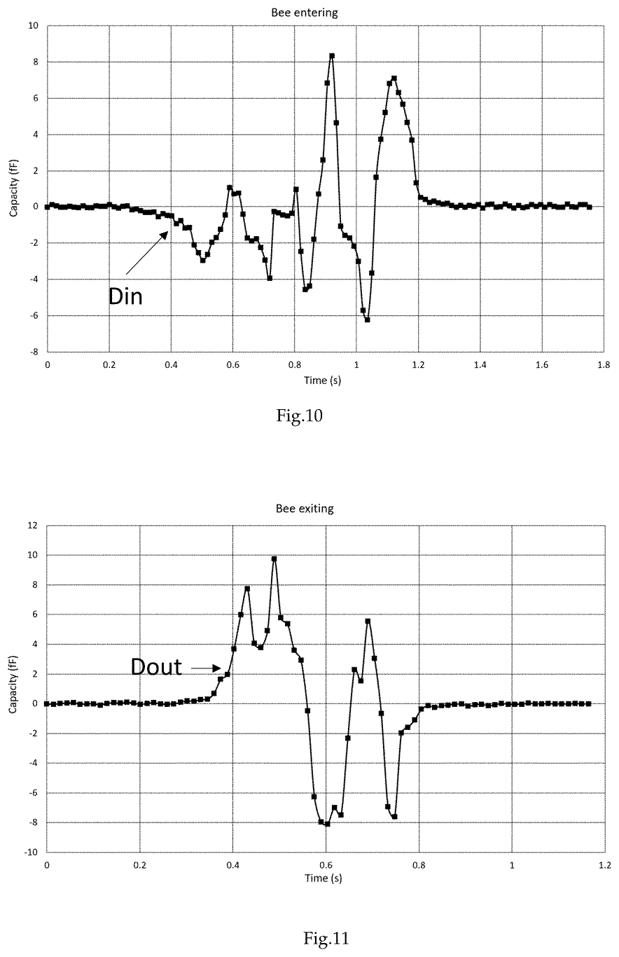

FIGS. 10 and 11 show the time trend of the differential capacitance (i.e., the difference in capacitance of the two capacitors) measured in the case of a bee entering and exiting the channel 112, respectively. As can be appreciated by looking at these figures, the crossing direction of the channel 112 can be distinguished by observing the initial trend of the differential capacitance signal which, in the case of entry into the hive, features an initial stretch (indicated with Din in FIG. 10) in which it decreases, while in the case of exit from the hive it features an initial stretch (indicated with Dout in FIG. 11) in which it increases.

FIGS. 10 and 11 show data acquired with experimental tests in the case of entry and exit of a bee into a beehive. At the output of the measuring circuit 900, however, output signals with different time trends may be obtained due to the particular movement of the bee in the channel 112 or to particular events. Consider, for example, the case in which a bee transports another dead bee outside the hive: in this case the exiting bees are two, but they may appear as a single insect of larger size. Similarly, events in which two or more bees enter one immediately after the other could be evidenced; again, the group of entering bees could be read as a single larger insect entering the hive.

In order to be able to correctly distinguish between all the various types of signals that may be presented at the output of the measuring circuit 900, an evaluation module 901 is provided in the example of FIG. 9, which exploits a neural network to perform a count of the bees entering and exiting the beehive.

The neural network uses an algorithm of the supervised learning type. Preferably the algorithm is of the feed forward type, but alternatively it is possible to use other algorithms of the supervised learning type, such as a recurrent network of the long short-term memory type.

Operationally, neural network learning is performed under the control of an operator. In detail, the passages of the bees through the channels 112 are recorded by means of cameras. When a bee enters or exits the beehive by crossing the channels 112, the measuring circuit 900 detects a change in capacitance of the capacitors which depends on the direction of movement of the bee, whether it is dragging another bee with it, etc. The operator visually verifies the measurement of the circuit 900 and labels it by choosing from one of the available classifications, e.g., entry of a single bee, exit of a single bee, simultaneous exit of two bees (e.g., by dragging a corpse), walk near the opening. This trains the neural network, which learns to distinguish between events by associating a measurement of the change in capacitance of the capacitors with a given cluster of events. Subsequently, in the realisation step of the device 100 the trained algorithm is therefore loaded into each evaluation module 901.

In the example of FIG. 9, the monitoring device 100 further comprises a transmission module 902—operationally connected to the evaluation module—capable of transmitting the counts of the passages of animals made by the evaluation module 901 to a remote centre. The transmission module 902 preferably comprises a memory unit and a radio transmission system. The transmission module 902 stores in the memory unit data—provided by the evaluation module 901—relating to the passages of animals through the passage openings 113 of the monitoring device 100. Periodically, the data stored in the memory unit are then transmitted to a remote centre via the radio transmission system. Depending on the application, the radio transmission system may be a Wi-Fi or Bluetooth module (in case the device is in the vicinity of a data collection centre) or a module for the connection to a mobile phone network, e.g., the radio transmission system may comprise circuitry of a mobile phone device and be capable of connecting to and transmitting data over a telephone network. Again, alternatively, the transmission module can connect to networks using other communication protocols, such as the low-bandwidth sigfox network.

The power supply of the system can be taken from an electrical network or, where not available, from an internal battery and/or from an energy harvesting system capable of recovering solar energy (e.g., by means of photovoltaic panels) or wind energy or mechanical and thermal energy generated by the bees, e.g., by means of piezoelectrics that are activated by the bees, or by means of Peltier cells that recover thermal energy generated by the bees. The different power supply systems can be used individually or in combination.

From the description of a preferred embodiment provided above, it is clear how the invention allows reaching the set objectives. The device to detect the passage of small animals through an opening is compact and easy to install. In general, this device does not even require the modification of the walking surface of the animal and is therefore not very invasive in the life of the monitored animal

However, it is clear that the examples provided above are not to be interpreted in a limiting way and the invention as conceived is subject to numerous modifications and variants all falling within the scope of the present invention according to the appended claims.

In particular, the modules and circuits described above may be implemented in different ways and be connected and/or integrated in different ways. For example, the device 100 may lack the evaluation module 901, described above. In this case, the device 100 would be provided with a detection module 1000 and the detected signals would be transmitted (preferably appropriately sampled and compressed) to a remote centre where the function of evaluating the passages in the channels 112 is delegated. Thus, in this embodiment, monitoring the crossing of openings by small animals is performed by a system comprising a local device monitoring an opening and a remote evaluation unit operatively connected to the local device.

Again, it is clear that the circuit in FIG. 9 is only one of the possible ways in which the change in capacitance due to the passage of an animal through the electrodes can be read.

In general, in order to monitor the passage of an animal through an opening, according to the present invention it is necessary to realise at least two capacitors arranged in sequence along a direction orthogonal to the plane of the monitored opening and with U-shaped electrodes. In the above example of FIGS. 2 to 11, three electrodes are provided, however, it is also possible to provide four electrodes to realise two capacitors, or to provide more than two electrodes to realise more than two capacitors.

Again, the crossing module 110 of FIG. 6 may be modified by providing separating walls 121 that separate two contiguous groups of electrodes 120. Each separating wall 121 connects the front wall 114 to the rear wall 115 and is arranged between two contiguous passage openings 113. The separating walls are preferably made of dielectric material but can also be made of metallic material.

In a further embodiment, the crossing module 110 may be made as a block of insulating material, for example obtained by plastic injection, in which the electrodes 120 are immersed. In this case the crossing module will always have a body with front, rear, side walls and a lower surface, which have the shapes described above, but which do not form a box-shaped body.

1-13. (canceled)

14. A system to detect the passage of a small animal through a monitored opening, the system comprising:
a first capacitor and a second capacitor arranged sequentially along a crossing direction passing through the monitored opening, wherein each of the first capacitor and the second capacitor are comprised of two substantially U-shaped electrodes configured to be placed in front of the opening to be monitored; and
an evaluation unit electrically connected to the two capacitors to evaluate the change in capacitance of the capacitors produced by the passage of an animal through the opening to be monitored.

15. The system according to claim 14, wherein the evaluation unit is configured to evaluate the difference in capacitance of the first and second capacitors, and to generate, as a function of the measured difference in capacitance, a signal indicating a direction of movement of the animal through the opening.

16. The system according to claim 14, wherein the first and second capacitor have a common electrode.

17. The system according to claim 14,
wherein the first and the second capacitor are placed inside a crossing module,
wherein the crossing module comprises a box body comprising a front wall, a rear wall, side walls connecting the front wall to the rear wall, and a lower surface closing the box body at the bottom,
wherein the rear wall and the front wall comprise a passage opening
wherein the lower surface of the crossing module comprises support areas from which channel walls rise up, wherein the channel walls define a passage channel between the passage opening of the front wall and the passage opening of the rear wall, and
wherein the electrodes are placed inside the crossing module and embrace the channel walls.

18. The system according to claim 17, wherein at least one of the front wall and the rear wall are made of metallic material.

19. The system according to claim 18, wherein the at least one metal wall is coated on the outside with an insulating material.

20. The system according to claim 17,
wherein the front wall and the rear wall further comprise at least a second passage opening,
wherein the lower surface comprises second channel walls that define at least a second channel between the second passage opening of the rear wall and the second opening of the front wall, and
wherein the crossing module further comprises a third and a fourth capacitor each comprising U-shaped electrodes embracing said second channel walls.

21. The system according to claim 20, wherein the box body further comprises a separating wall that connects the front wall to the rear wall and is arranged between the first passage opening and the second passage opening.

22. The system according to claim 14, wherein the evaluation unit further comprises a neural network of the supervised learning type.

23. The system according to claim 22, wherein the neural network is realised by a feed forward algorithm, or a recurrent network of the long short-term memory type.

24. The system according to claim 17,
wherein the crossing module is included in a monitoring device, and wherein the rear wall of the crossing module corresponds to the rearmost wall, in the direction of crossing the channel, of the monitoring device.

25. The system according to claim 24,
wherein the monitoring device further comprises a housing for a data transmission system, and
wherein the housing is connected to the crossing module, is arranged above the crossing module and has a rear wall aligned with the rear wall of the crossing module.

26. A beehive, comprising:
an opening for the entry and exit of bees;
a first capacitor and a second capacitor arranged sequentially along a crossing direction passing through the monitored opening, wherein each of the first capacitor and the second capacitor are comprised of two substantially U-shaped electrodes configured to be placed in front of the opening to be monitored; and
an evaluation unit electrically connected to the two capacitors to evaluate the change in capacitance of the capacitors produced by the passage of an animal through the opening to be monitored, wherein the first and second capacitor are arranged in front of the opening for the entry and exit of bees.
